(19) United States
(12) Patent Application Publication
(10) Pub. No.: US 2024/0426605 A1
(43) Pub. Date: Dec. 26, 2024

(54) PATTERN SHAPE MEASUREMENT METHOD, PATTERN SHAPE MEASUREMENT APPARATUS, AND METHOD FOR PRODUCING SEMICONDUCTOR DEVICE

(71) Applicant: Kioxia Corporation, Tokyo (JP)

(72) Inventor: Taiki ITO, Kawasaki (JP)

(73) Assignee: Kioxia Corporation, Tokyo (JP)

(21) Appl. No.: 18/743,427

(22) Filed: Jun. 14, 2024

(30) Foreign Application Priority Data
Jun. 20, 2023 (JP) 2023-100784

(51) Int. Cl. G01B 15/04; G03F 1/86; G03F 7/00; G06F 30/32; G06T 7/00; G06T 7/12; G06T 7/50

(52) U.S. Cl. CPC G01B 15/04; G03F 1/86; G03F 7/705; G03F 7/70508; G06F 30/32; G06T 7/001; G06T 7/12; G06T 7/50; G06T 2207/30148

(57) ABSTRACT

A pattern shape measurement method includes generating, based on shape data on a pattern being a measurement target, contour point data including pieces of position information on contour points of the pattern (e.g., mask pattern); selecting sets of pieces of position information on consecutive contour points from the contour point data and generating a plurality of items of extracted point data including the respective sets of pieces of position information on consecutive contour points; calculating, with circuitry, for each of the plurality of items of extracted point data, a determined angle formed between a marker line based on the consecutive contour points and a base line that extends in a prescribed direction in the pattern; determining a scan angle for the charged particles with respect to the pattern based on a frequency of occurrence of the determined angle; and scanning the pattern at the determined scan angle.

### CROSS-REFERENCE TO RELATED APPLICATION

This application is based upon and claims the benefit of priority from Japanese Patent Application No. 2023-100784, filed Jun. 20, 2023, the entire contents of which are incorporated herein by reference.

### FIELD

Embodiments described herein relate generally to a pattern shape measurement method, a pattern shape measurement apparatus, and a method for producing a semiconductor device.

### BACKGROUND

In a production process of a photomask used in a lithography step in semiconductor device production, an inverse lithography technology (ILT) technique, which determines a shape of a mask pattern by solving an inverse problem from an optical image, is used. A shape of a mask pattern to which the ILT technique is applied may tend to be complex.

To specify a shape of a pattern formed on a substrate such as a photomask, a critical dimension scanning electron microscope (CD-SEM) is used. The CD-SEM scans a pattern being a measurement target with an electron beam and detects peaks of secondary electrons that are highlighted in a form of pattern edges or the like, thus measuring dimensions of the pattern.

However, on a pattern edge extending substantially parallel to a scan direction of the electron beam, continuously generated secondary electrons are drawn toward a substrate that is positively charged, making peaks of the secondary electrons unclear, which may decrease an accuracy in measuring dimensions. Such a phenomenon may deteriorate an accuracy in measuring a pattern to which the ILT technique or the like is applied, and that has a complex shape.

One, non-limiting, aspect of an embodiment is to provide a pattern shape measurement method, a pattern shape measurement apparatus, a method for producing a semiconductor device capable of measuring a shape of a pattern with high accuracy.

### BRIEF DESCRIPTION OF THE DRAWINGS

FIG. 1 is a block diagram illustrating an example of a configuration of a pattern shape measurement apparatus according to an embodiment.

FIG. 2 is a diagram schematically illustrating an example of a configuration of a measurement mechanism according to the embodiment.

FIG. 3 is a diagram with parts FIG. 3(a) and FIG. 3(b) schematically illustrating an example of a configuration of a mask substrate according to the embodiment.

FIG. 4 is a diagram illustrating an example of image data according to the embodiment.

FIG. 5 is a diagram with parts FIG. 5(a) and FIG. 5(b) illustrating an example of contour point data according to the embodiment.

FIG. 6 is a diagram illustrating, in parts FIG. 6(a) and FIG. 6(b), a table showing an example of extracted point data according to the embodiment.

FIG. 7 is a diagram for describing a method for calculating an angle according to the embodiment.

FIG. 8 is a histogram illustrating frequencies of angles according to the embodiment.

FIG. 9 is a diagram for describing a production process for a photomask in a production process for a semiconductor device according to the embodiment.

FIG. 10 is a diagram for describing a pattern shape measurement method in the production process for a semiconductor device according to the embodiment.

FIG. 11 is a diagram for describing the production process for a semiconductor device according to the embodiment.

FIG. 12 is a diagram illustrating an example of extracted point data according to Modified Example 1.

FIG. 13 is a diagram illustrating a method for generating extracted point data according to Modified Example 2.

FIG. 14 is a table showing an example of a relationship between items of extracted point data and weights according to Modified Example 3.

FIG. 15 is a diagram with parts FIG. 15(a) and FIG. 15(b) illustrating a method for determining a scan angle according to Modified Example 4.

FIG. 16 is a graph for describing a method for determining scan angles according to Modified Example 5.

### DETAILED DESCRIPTION

Various embodiments will be described hereinafter with reference to the accompanying drawings.

In general, according to one embodiment, a pattern shape measurement method includes generating, based on shape data on a pattern being a measurement target, contour point data including pieces of position information on contour points of the pattern (e.g., mask pattern), selecting sets of pieces of position information on consecutive contour points from the contour point data and generating a plurality of items of extracted point data including the respective sets of pieces of position information on consecutive contour points, calculating, with circuitry, for each of the plurality of items of extracted point data, a determined angle formed between a marker line based on the consecutive contour points and a base line that extends in a prescribed direction in the pattern, determining a scan angle for charged particles with respect to the pattern based on a frequency of occurrence of the angle, and scanning the pattern at the scan angle.

### Embodiment

Hereinafter, an embodiment of the present invention will be described in detail with reference to the drawings. Note that the following embodiment should not be construed as limiting the present invention. Furthermore, constituent components in the following embodiment include those that can be easily figured out by those skilled in the art or are substantially the same.

### (Configuration Example of Pattern Shape Measurement Apparatus)

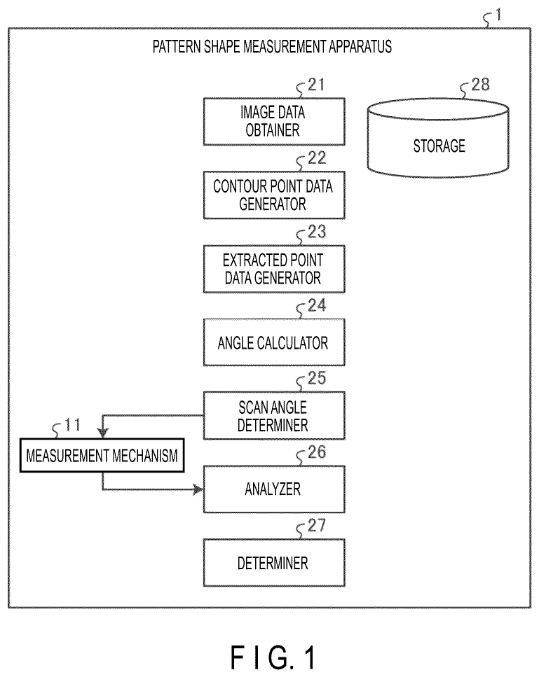

FIG. 1 is a block diagram illustrating an example of a configuration of a pattern shape measurement apparatus 1 according to an embodiment.

The pattern shape measurement apparatus 1 illustrated in FIG. 1 is an apparatus capable of measuring a shape of a pattern formed on a mask substrate by scanning the mask substrate with an electron beam. Specifically, the pattern shape measurement apparatus 1 determines a scan angle of the electron beam with respect to the mask substrate, scans the mask substrate with the electron beam at the scan angle, and measures the shape of the pattern based on a captured image generated as a result of the scan. In the present embodiment, the pattern shape measurement apparatus 1 capable of executing such shape measurement processing is configured in a form of, for example, a critical-dimension scanning electron microscope (CD-SEM). The electron beam is an example of charged particles.

The pattern shape measurement apparatus 1 includes, as functional units for executing the shape measurement processing, a measurement mechanism 11, an image data obtainer 21, a contour point data generator 22, an extracted point data generator 23, an angle calculator 24, a scan angle determiner 25, an analyzer 26, a determiner 27, and a storage 28. These functional constituent components can be implemented by cooperation of hardware such as one or more CPUs that execute software code described later, as well as other circuitry such as application specific integrated circuitry (ASIC) or programmable array logic (PAL).

First, the measurement mechanism 11 will be described. The measurement mechanism 11 is a physical and mechanical component of the pattern shape measurement apparatus 1. The measurement mechanism 11 emits the electron beam to the mask substrate at a prescribed scan angle. As the prescribed scan angle, the measurement mechanism 11 can use, for example, 0° that is taken as a reference or a scan angle that is determined by the scan angle determiner 25 described later.

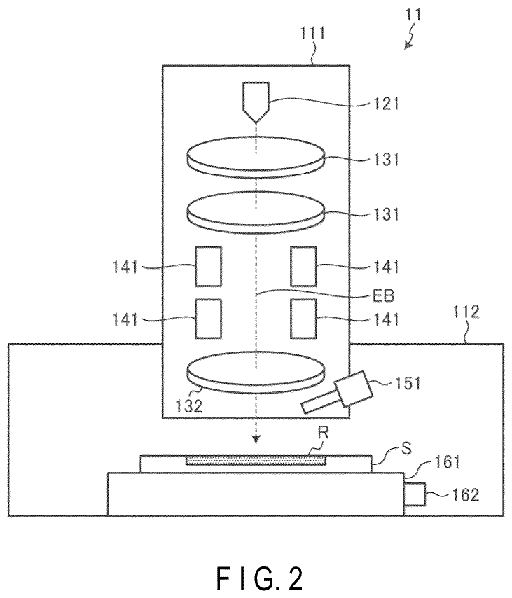

FIG. 2 is a diagram schematically illustrating an example of a configuration of the measurement mechanism 11 according to the embodiment. As illustrated in FIG. 2, the measurement mechanism 11 includes a column 111 in which an electron gun 121 serving as an emission source of an electron beam EB as charged particles is installed, a sample chamber 112 in which a mask substrate S is placed, and a controller (e.g., dedicated or programmable circuitry) that controls parts of the measurement mechanism 11.

The column 111 is in a cylindrical shape. The column 111 includes an upper end portion that is closed and a lower end portion that is opened to allow the electron beam EB to pass. The sample chamber 112 is configured to house the mask substrate S. The column 111 and the sample chamber 112 are combined together in a state where the column 111 and the sample chamber 112 are airtightly sealed. An inside of the column 111 and an inside of sample chamber 112 are configured to be kept under a reduced pressure by a pump or the like not illustrated.

In the column 111, the electron gun 121, convergent lenses 131, an objective lens 132, coils 141, and a detector 151 are installed in this order from a vicinity of the upper end portion.

The electron gun 121 emits the electron beam EB downward in the column 111. The electron beam EB emitted by the electron gun 121 travels along a longitudinal direction of the column 111.

The convergent lenses 131 are electromagnetic coils that are wound into concentrically about an optical axis of the column 111. The convergent lenses 131 converge the electron beam EB with their magnetic fields.

The objective lens 132 is an electromagnetic coil that is wound into concentrically about the optical axis of the column 111. The objective lens 132 converges the electron beam EB emitted toward the mask substrate S with its magnetic field.

The coils 141 are electromagnetic coils that are provided in pairs for deflecting or performing astigmatism correction on the converged electron beam EB. The coils 141 are arranged symmetrically to each other about the optical axis of the column 111. The coils 141 scan an observation region R on the mask substrate S with the converged electron beam EB with respect to the prescribed scan angle. The prescribed scan angle is, for example, a scan angle that is determined by the scan angle determiner 25 described later. The coils 141 can scan the mask substrate S with the electron beam EB a plurality of times.

The detector 151 detects secondary electrons or backscattered electrons that are produced as a result of scanning the observation region R at the prescribed scan angle. Based on a signal amount of the detected secondary electrons or backscattered electrons, the detector 151 images the observation region R. In this manner, a captured image of the observation region R is generated.

In the sample chamber 112, a stage 161 on which the mask substrate S is set is installed. To the stage 161, an actuator 162 is attached. The actuator 162 is configured to drive the stage 161 right and left and backward and forward. Driving the stage 161 enables observation of a desired observation region R on the mask substrate S.

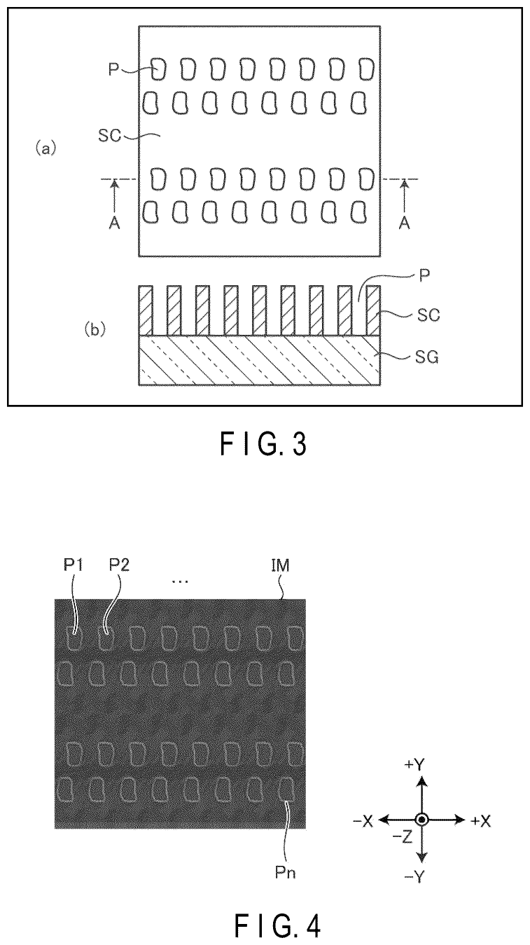

With reference to FIG. 3(A) and FIG. 3(B), the mask substrate S that is a measurement target and has opening patterns P will be described. FIG. 3(A) and FIG. 3(B) are diagrams schematically illustrating an example of a configuration of the mask substrate S according to the embodiment. FIG. 3(A) is a top view of the mask substrate S, and FIG. 3(B) is a sectional view taken along the line A-A in FIG. 3(A).

As illustrated in FIGS. 3(A) and 3(B), the mask substrate S has a structure in which a light shielding coating SC is provided on a top surface of a glass substrate SG. The light shielding coating SC blocks exposure light in exposure processing. Portions of the mask substrate S that are not provided with the light shielding coating SC are the opening patterns P. The opening patterns P are closed patterns each having a curved shape and arranged side by side on the mask substrate S. Exposure light passes through the opening patterns P during exposure processing.

The mask substrate S illustrated in FIGS. 3(A) and 3(B) is generated based on prescribed design data and drawing data. The design data is data including layout information on a pattern desired to be formed on a wafer. The drawing data is data including layout information on the opening patterns P and the like to be formed on the mask substrate S. The drawing data is the design data corrected so that the desired pattern is formed on the wafer. The design data and the drawing data are generated with a design device not illustrated and are stored in the storage 28 of the pattern shape measurement apparatus 1.

Referring back to FIG. 1, the image data obtainer 21 obtains image data IM on the mask substrate S. The image data IM is a captured image that is generated by, for example, the measurement mechanism 11 described above. The image data IM is an example of shape data.

FIG. 4 is a diagram illustrating an example of image data IM according to the embodiment.

In the present specification, a right-left direction in each of the drawings including FIG. 4 and subsequent drawings is defined as an X axis, and an up-down direction of each of the drawings is defined as a Y axis, for convenience of description. In addition, a direction that intersects the X axis and the Y axis is defined as a Z axis. Directions indicated by arrows of the X axis, the Y axis, and the Z axis are taken as a positive X direction, a positive Y direction, and a positive Z direction, and opposite directions to the arrows are taken as a negative X direction, a negative Y direction, and a negative Z direction, respectively.

Specifically, the image data IM illustrated in FIG. 4 is generated by the measurement mechanism 11 scanning the mask substrate S set on the stage 161 with the electron beam EB at a given scan angle. The given scan angle is an angle that serves as a reference, such as 0°.

The image data IM includes an image of a plurality of opening patterns P1 to Pn (n is an integer equal to or greater than one). Note that the opening patterns P1 to Pn may be referred to as the “opening patterns P” when the opening patterns P1 to Pn are not distinguished from one another. The opening patterns P are an example of a pattern that is a measurement target. Such image data IM is stored in the storage 28. The image data obtainer 21 obtains the image data IM from the storage 28.

Referring back to FIG. 1, based on the image data IM, the contour point data generator 22 generates contour point data 100. The contour point data 100 includes position information on contour points T of the opening patterns P.

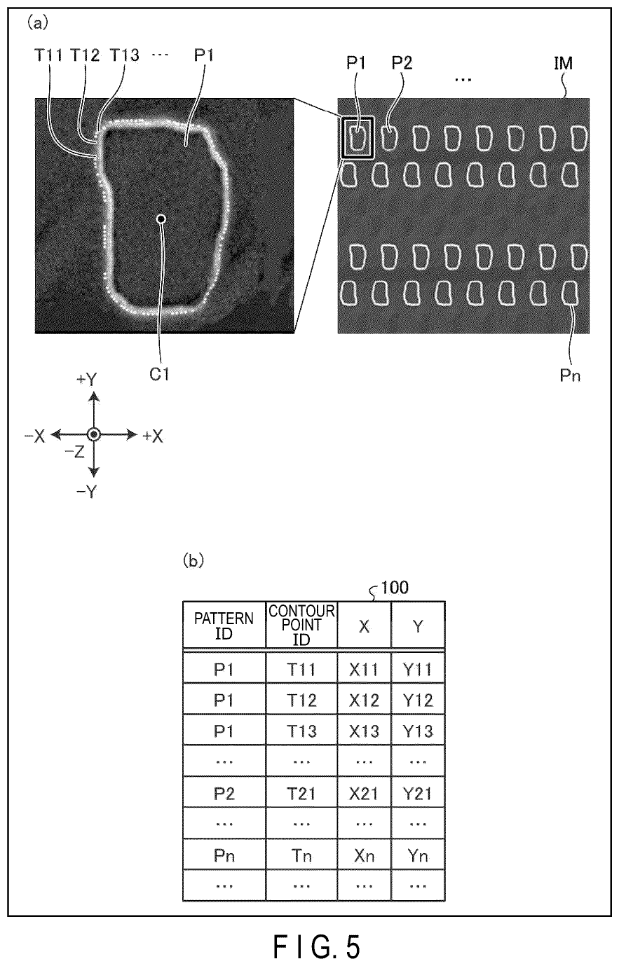

FIG. 5(A) and FIG. 5(B) are, respectively, a diagram illustrating, and a table showing, an example of the contour point data 100 according to the embodiment. The diagram in FIG. 5(A) illustrates the image data IM and the contour point data 100 in a superimposing manner. The table in FIG. 5(B) shows the contour point data 100 in which opening pattern IDs, contour point IDs, and pieces of position information on the contour points T are associated with one another. The opening pattern IDs in FIG. 5(B) are for identifying P1 to Pn illustrated in FIG. 5(A). The contour point IDs are for identifying the contour points T of the opening patterns P. The pieces of position information on the contour points T are pieces of coordinate information each including an X coordinate and a Y coordinate.

Specifically, based on the image data IM, the contour point data generator 22 specifies pieces of coordinate information as the pieces of position information on the contour points T of the opening pattern P and generates the contour point data 100 based on the specified pieces of coordinate information. The contour points T are for specifying pattern edges of the opening patterns P. Based on the contour points T, respective shapes and dimensions of the opening patterns P are defined.

For example, in the example in FIG. 5(A), the contour point data generator 22 generates a luminance profile based on a grayscale of pixels along a radial direction from a central point C1 of the opening pattern P1. Based on the luminance profile, the contour point data generator 22 specifies a position at which a luminance reaches a maximum as, for example, a contour point T11. In this manner, the contour point data generator 22 specifies pieces of coordinate information on the contour points T on the entire circumference of the opening pattern P1.

The contour point data generator 22 executes such processing of specifying the pieces of coordinate information on the contour points T on the opening patterns P1 to Pn included in the image data IM. In this manner, the contour point data generator 22 generates the contour point data 100 including the pieces of coordinate information on the contour points T of the opening patterns P1 to Pn.

Based on the contour point data 100, the extracted point data generator 23 generates a plurality of items of extracted point data 200. The items of extracted point data 200 each include pieces of position information of two consecutive contour points T selected from the contour point data 100.

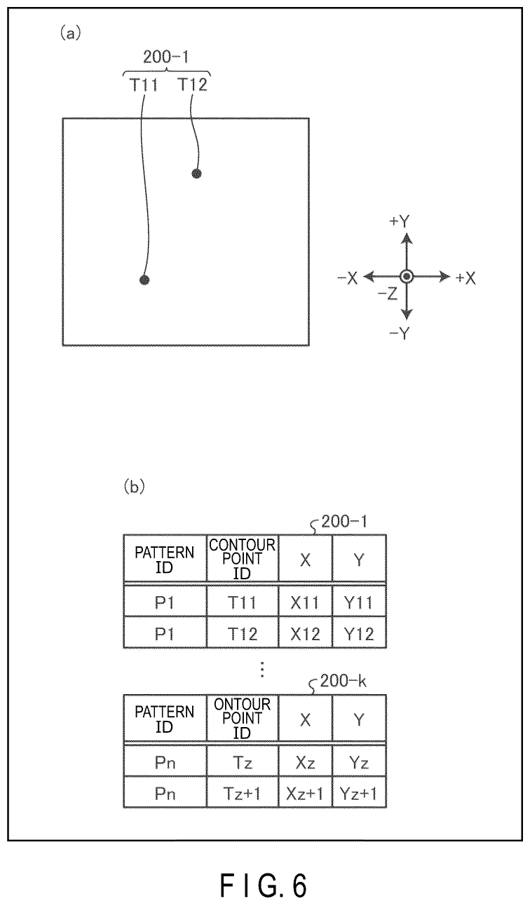

FIG. 6(A) and FIG. 6(B) are, respectively, a diagram illustrating, and a table showing, an example of the extracted point data 200 according to the embodiment. The diagram in FIG. 6(A) illustrates an image including one of the plurality of items of extracted point data 200. The table in FIG. 6(B) shows each of the plurality of items of extracted point data 200 in which the opening pattern IDs, the contour point IDs, and the pieces of position information on the contour points T are associated with one another.

As illustrated and shown in FIG. 6(A) and FIG. 6(B), the extracted point data generator 23 extracts, for example, two consecutive contour points T11 and T12 from the contour point data 100. The extracted point data generator 23 generates a set of the extracted contour points T11 and T12 as extracted point data 200-1. The extracted point data generator 23 continues processing of the extraction described above until every contour point T included in the contour point data 100 is extracted at least once, thus generating items of extracted point data 200-1 to 200-k (k is an integer equal to or greater than one).

Note that the items of extracted point data 200-1 to 200-k may be hereinafter referred to as the “items of extracted point data 200” when the items of extracted point data 200-1 to 200-k are not distinguished from one another.

The angle calculator 24 calculates, for each of the plurality of generated items of extracted point data 200, an angle α formed between a marker line DL that connects two consecutive contour points T and a base line BL that extends along the X direction in the image data IM. The X direction is an example of a prescribed direction.

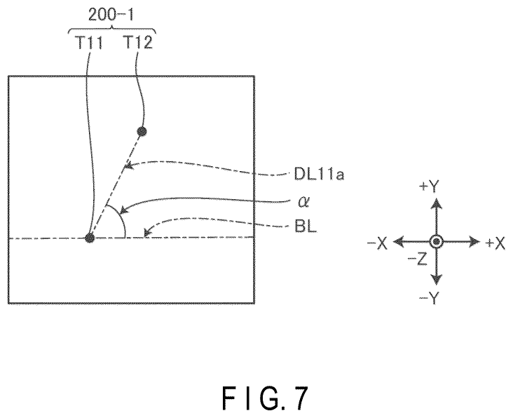

FIG. 7 is a diagram for describing a method for calculating the angle α according to the embodiment. FIG. 7 illustrates the extracted point data 200-1, which is described with reference to FIG. 6(A).

Specifically, for example, as illustrated in FIG. 7, the angle calculator 24 defines the base line BL extending along the X direction. Here, it is assumed that the base line BL passes the contour point T11 and extends in the X direction, for convenience of description. The angle calculator 24 defines a marker line DL11a that passes the contour points T11 and T12. The angle calculator 24 calculates the angle α formed between the base line BL and the marker line DL11a. Thus, an orientation of the marker line DL11a with respect to the base line BL is specified. The orientation of the marker line DL11a with respect to the base line BL exactly corresponds to an orientation of a pattern edge that is specified with the contour points T11 and T12.

The angle calculator 24 calculates the angle α on each of the plurality of items of extracted point data 200.

The scan angle determiner 25 determines a scan angle of the electron beam EB based on frequencies (or more particularly, frequencies of occurrence) of the calculated angles α. Specifically, the scan angle determiner 25 determines an angle α that has a lowest frequency of occurrence of the plurality of angles α, as the scan angle of the electron beam EB. For convenience, “frequency” is sometimes used as an abbreviation for “frequency of occurrence”.

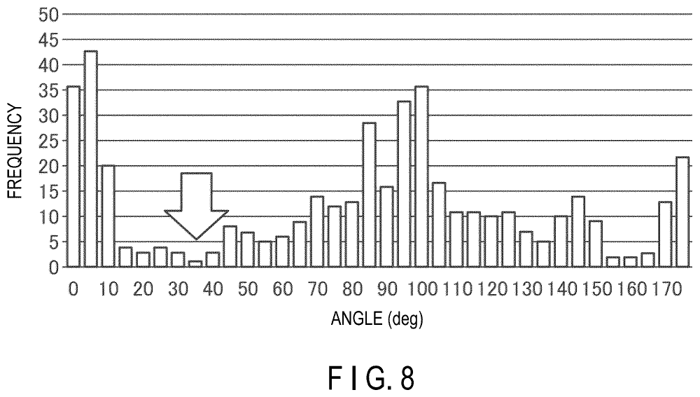

FIG. 8 is a histogram H illustrating the frequencies of occurrence of the angles α according to the embodiment. In the histogram H exemplified in FIG. 8, its horizontal axis represents angle α, and its vertical axis represents frequency (or frequency of occurrence) of angle α. The horizontal axis is divided into 5° ranges. Frequencies of angles α included in each range are integrated (accumulated in an aggregate sum) and indicated on the vertical axis.

More specifically, when frequencies of angles α within a specific range are lowest (fewest), the scan angle determiner 25 determines a specific angle included in the specific range as the scan angle of the electron beam EB. For example, in the example illustrated in FIG. 8, when frequencies of “35° or greater and 40° or less” as the specific range are lowest, the scan angle determiner 25 determines, as the scan angle of the electron beam EB, “35°” as the specific angle included in “35° or greater and less than 40°.” Note that the histogram H in FIG. 8 may be represented as probability of occurrence.

The scan angle determiner 25 outputs the determined scan angle of the electron beam EB to the measurement mechanism 11. Thus, the measurement mechanism 11 can scan the opening patterns P with electron beam EB at the determined scan angle. In turn, by using this determined scan angle, the determined scan angle will be least often aligned with (or substantially parallel to) a direction in which secondary electrons are emitted, thus allowing for a higher quality scan in which the electron beam is mainly moved in a direction that traverses across (not along) a pattern edge.

The analyzer 26 executes measurement of shapes of the opening patterns P based on the captured image generated by the measurement mechanism 11. Specifically, for example, the analyzer 26 measures the shapes of the opening patterns P by executing model fitting or the like based on the captured image. Note that it is assumed that measuring the shapes of the opening patterns P in the present embodiment includes specifying dimensions of the opening patterns P.

The determiner 27 determines whether the shapes of the opening patterns P are within a range indicated by a reference value. The reference value is determined when design data on the opening patterns P is generated. The reference value is stored in the storage 28.

The storage 28 stores, for example, the image data IM generated by the measurement mechanism 11. The storage 28 also stores, for example, the design data and drawing data on the mask substrate S generated by the design device not illustrated and position information, in the drawing data, on a region of interest from which the finish of the mask substrate S can be evaluated. The storage 28 also stores, for example, a reference value for determining a quality of a shape of the opening pattern P, a reference value for determining a quality of a shape of a transferred pattern, which will be described later, formed on a wafer.

The pattern shape measurement apparatus 1 according to the embodiment described above is configured as, for example, a computer including a central processing unit (CPU), a read only memory (ROM), and a random access memory (RAM), where the computer is configured by its execution of software code. The functional units described above are implemented by the CPU of the pattern shape measurement apparatus 1 loading a program (software code, which as computer readable instructions) stored in the ROM or the like onto the RAM and executing the program.

### (Production Process for Semiconductor Device)

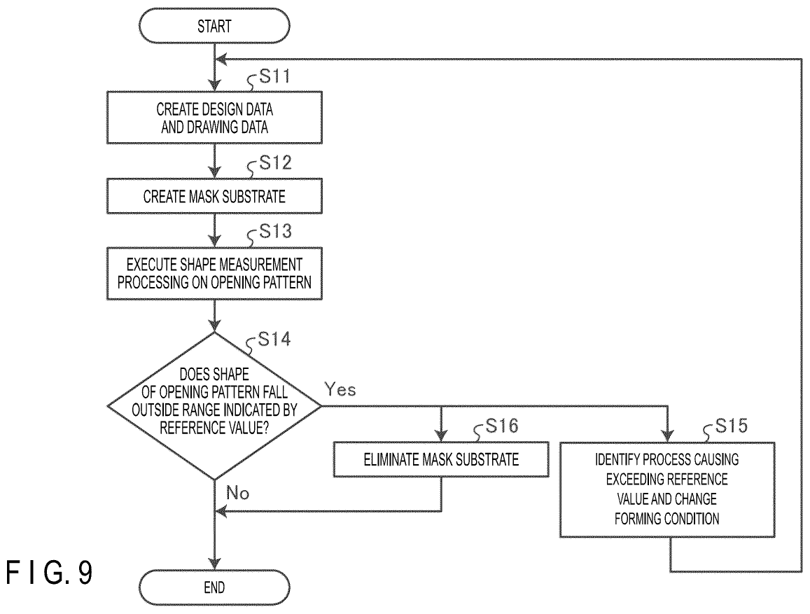

With reference to FIG. 9 to FIG. 11, a production process for a semiconductor device will be described. FIG. 9 is a diagram for describing a production process for a photomask in the production process for a semiconductor device according to the embodiment. The production process for a photomask in FIG. 9 is performed as a part of the production process for a semiconductor device.

### (Production Process for Photomask)

First, a design device not illustrated creates design data and drawing data of a mask substrate S (S11).

Next, the mask substrate S is created based on the drawing data (S12). On the mask substrate S, opening patterns P are formed under a prescribed forming condition. On the formed opening patterns P, the pattern shape measurement apparatus 1 executes pattern shape measurement processing (S13).

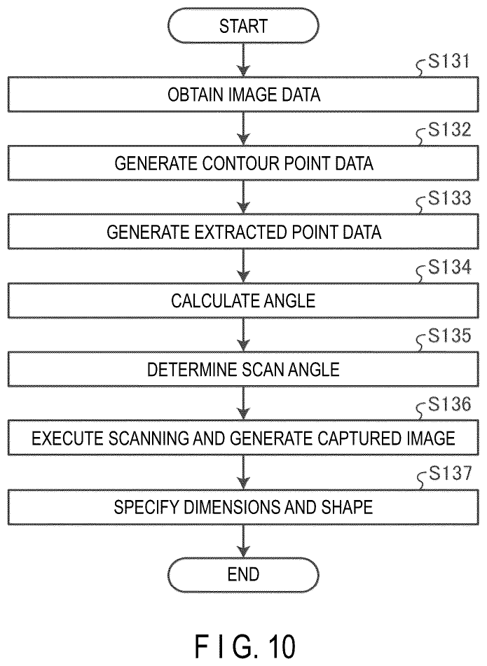

Here, with reference to FIG. 10, steps of the pattern shape measurement processing executed by the pattern shape measurement apparatus 1 will be described. FIG. 10 is a diagram for describing the pattern shape measurement processing in the production process for a semiconductor device according to the embodiment. The pattern shape measurement processing in FIG. 10 is performed as a part of the production process for a photomask and the production process for a semiconductor device.

The image data obtainer 21 obtains image data IM on the mask substrate S (S131). The image data IM is obtained beforehand by scanning the opening patterns P with an electron beam EB.

Based on the image data IM, the contour point data generator 22 generates contour point data 100 (S132). The contour point data 100 includes position information on the contour points T of the opening patterns P included in the image data IM.

Based on the contour point data 100, the extracted point data generator 23 generates a plurality of items of extracted point data 200 (S133). Specifically, the extracted point data generator 23 selects pieces of position information on two consecutive contour points T from the contour point data 100 and generates an item of extracted point data 200 including the selected pieces of position information on the contour points T.

The angle calculator 24 calculates an angle α for each of the plurality of items of extracted point data 200 (S134). Specifically, for each of the items of the extracted point data 200, the angle calculator 24 calculates an angle α formed between a marker line DL based on consecutive contour points T and a base line BL extending in the X direction in an opening pattern P.

The scan angle determiner 25 determines a scan angle of the electron beam EB based on frequencies of the calculated angles α (S135). Specifically, the scan angle determiner 25 determines an angle α that has a lowest frequency of the plurality of angles α, as the scan angle of the electron beam EB. The scan angle determiner 25 outputs the determined scan angle of the electron beam EB to the measurement mechanism 11.

The measurement mechanism 11 scans the opening patterns P at the scan angle determined by the scan angle determiner 25 and generates a captured image (S136).

Based on the generated captured image, the analyzer 26 specifies the shapes of the opening patterns P (S137). The shapes of the opening patterns P are an example of measurement data.

In this manner, the pattern shape measurement processing in the embodiment is finished.

Note that, in a case where a plurality of mask substrates S of the same type are created in step S12 of the production process for a photomask in the embodiment illustrated in FIG. 9, processing in steps S131 to S135 of the pattern shape measurement processing in FIG. 10 may be executed on only one of the created mask substrates S, for example. Then, using the scan angle determined in step S135, processing in step S136 and the subsequent step may be executed on all of the created mask substrates S.

Referring back to FIG. 9, the determiner 27 of the pattern shape measurement apparatus 1 determines whether any one of the shapes of the opening patterns P falls outside a range indicated by a reference value (S14).

When the determiner 27 determines that any one of the shapes of the opening patterns P falls outside the range indicated by the reference value (S14→YES), a process that causes the any one of the shapes to exceed the reference value is identified, and the forming condition for the opening patterns P is changed to an appropriate condition (S15). Then, a mask substrate S determined as having any one of the shapes falling outside the range indicated by the reference value is eliminated (S16). At this time, alternatively, whether to eliminate all the mask substrates S may be determined with consideration given collectively to, for example, passes or fails in other inspection items.

When the determiner 27 determines that the shapes of the opening patterns P are within the range indicated by the reference value (S14→NO), the processing is finished.

Through the processing described above, the mask substrate S in the embodiment is produced. The mask substrate S produced in this manner is to be used for producing a semiconductor device.

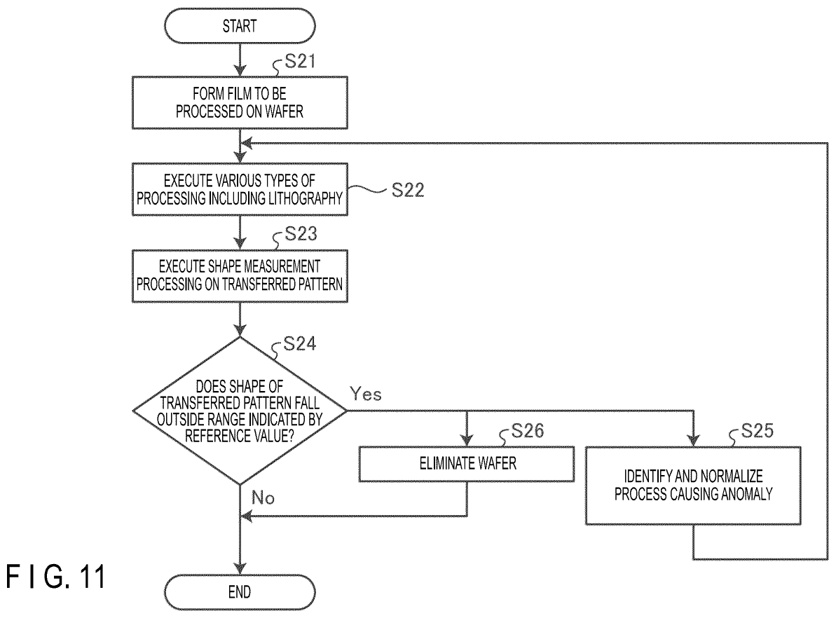

FIG. 11 is a diagram for describing the production process for a semiconductor device according to the embodiment. The production process for a photomask in FIG. 9 and the pattern shape measurement processing in FIG. 10 are performed as parts of the production process for a semiconductor device illustrated in FIG. 11.

A wafer serving as a substrate to be processed in the production process for a semiconductor device is made of, for example, silicon. First, a film to be processed is formed on the wafer (S21). The film to be processed is a film being a processing subject. The film to be processed is, for example, a single layer film such as a silicon dioxide film or a silicon nitride film, or a laminated film in which a plurality of films are laminated together.

Next, on the film to be processed, various types of processing including lithography using the mask substrate S are executed (S22). The various types of processing executed at this time are performed under respective prescribed forming conditions. Thus, a plurality of transferred patterns including the transferred opening patterns P of the mask substrate S are formed on the wafer. The transferred patterns are an example of a pattern.

Based on the plurality of transferred patterns formed on the wafer, the pattern shape measurement apparatus 1 executes the pattern shape measurement processing, which is described with reference to FIG. 10 (S23).

The determiner 27 determines whether any one of shapes of the transferred patterns falls outside a range indicated by a reference value (S24).

When the determiner 27 determines that any one of the shapes of the transferred patterns falls outside the range indicated by the reference value (S24→YES), a process that causes the any one of the shapes to exceed the reference value is identified, and the forming condition for the transferred patterns is changed (S25). Then, a wafer determined as having any one of the shapes falling outside the range indicated by the reference value is eliminated (S26). At this time, alternatively, whether to eliminate all the mask substrates S may be determined with consideration given collectively to, for example, passes or fails in other inspection items.

When the determiner 27 determines that the shapes of the transferred patterns formed on the wafer are within the range indicated by the reference value (S25→NO), the processing is finished.

Through the processing described above, the semiconductor device in the embodiment is produced.

### Comparative Example

In the production process of semiconductor devices, an anomaly in shape of a pattern on a mask substrate or a pattern on a wafer has a significant influence on a yield of the semiconductor devices. Thus, there is a demand for increasing accuracies in measuring shapes of the patterns.

In a CD-SEM used in such measurement of shapes, a shape of a pattern as a measurement target is conventionally defined by scanning the pattern with an electron beam in a prescribed direction and detecting peaks of secondary electrons that are highlighted in a form of opposite pattern edges. However, there may be such a problem that a peak of secondary electrons is unclear on a pattern edge extending substantially parallel to a scan direction. This is because, at a location to which the electron beam is applied, a large number of secondary electrons are emitted, which causes the measurement target to be relatively positively charged at the location, and thus secondary electrons emitted at a location next irradiated with the electron beam are pulled back toward the location of the previous application on the measurement target. Therefore, it has been said that, in a CD-SEM, an electron beam is desirably moved in a direction crossing opposite pattern edges.

Conventionally, the ILT technique has been used for generating a mask substrate in a production process for a semiconductor device. The ILT technique is known for its effect of expanding a process margin of a transferred pattern transferred on a wafer and its effect of enhancing a fidelity of a shape of a transferred pattern for an opening pattern on a mask. On the other hand, a pattern to which the ILT technique is applied may have a complex, curved shape.

The problem described above that can occur in shape measurement with a CD-SEM may weigh against, for example, shape measurement of a pattern to which the ILT technique is applied. This is because, on a pattern having a complex, curved shape, a peak of secondary electrons becomes unclear at many locations on pattern edges, making it difficult to provide opposite pattern edges with clear peaks.

### SUMMARY

In a pattern shape measurement method in the embodiment, pieces of position information on two consecutive contour points T are selected based on image data IM on an opening pattern P. An angle α formed between a marker line DL connecting the two consecutive contour points T and a base line BL extending in a prescribed direction in the opening pattern P is calculated. Then, based on frequencies of occurrence of angles α, a scan angle of an electron beam EB to the opening pattern P is determined.

Thus, a scan direction of the electron beam EB can be determined based on an orientation of each of pattern edges included in contour points of the opening pattern P, making peaks of produced secondary electrons clearer. As a result, a shape of the opening pattern P can be measured with high accuracy.

In the pattern shape measurement method in the embodiment, an angle α having a lowest frequency of a plurality of angles α is determined as the scan angle of the electron beam EB. Thus, it is possible to reduce a probability that, on a pattern edge of the opening pattern P, the scan direction of the electron beam EB is substantially parallel to an orientation of the pattern edge. Therefore, the shape of the opening pattern P can be measured with higher accuracy.

### Modified Example 1

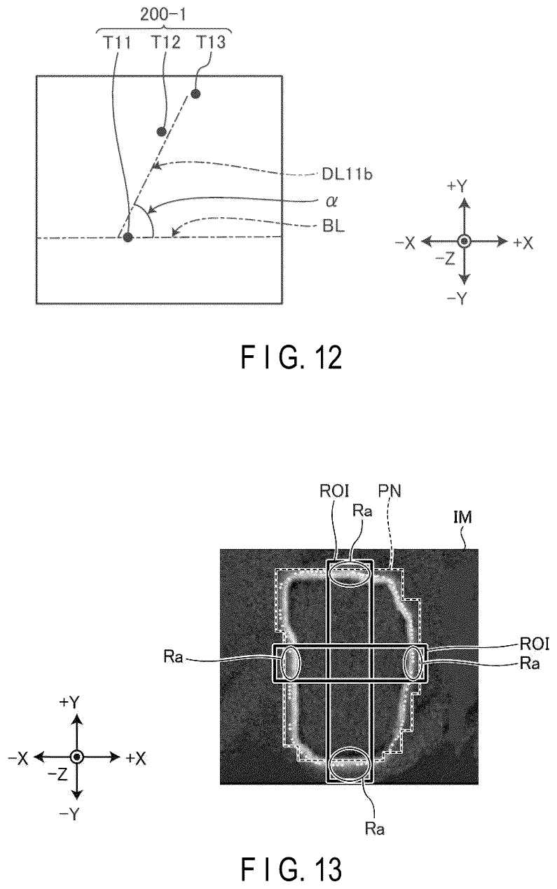

With reference to FIG. 12, Modified Example 1 of the embodiment will be described in detail. A pattern shape measurement method and a pattern shape measurement apparatus in Modified Example 1 differ from those in the embodiment described above in that three consecutive contour points T are extracted as an item of extracted point data 200. Note that, in the following, the same components as in Embodiment 1 described above will be denoted by the same reference characters, and descriptions thereof may be omitted.

FIG. 12 is a diagram illustrating an example of extracted point data 200 according to Modified Example 1. Note that, in the pattern shape measurement method in Modified Example 1 as well, the processing of steps S131 to 132 in FIG. 10 is assumed to be executed beforehand.

The extracted point data generator 23 extracts three consecutive contour points T from the contour point data 100 and generates a plurality of items of extracted point data 200. As illustrated in FIG. 12, for example, the extracted point data generator 23 extracts pieces of position information on three consecutive contour points T11 to T13 from the contour point data 100 and generates extracted point data 200-1.

The angle calculator 24 defines a marker line DL11b based on the extracted contour points T11 to T13. For the definition of the marker line DL11b, for example, approximation by a regression analysis method is used. The angle calculator 24 calculates an angle α formed between the base line BL and the marker line DL11b. The angle calculator 24 executes processing of the calculation of the angle α on each of a plurality of items of extracted point data 200 that includes three contour points T.

Subsequently, processing of step S135 and the subsequent steps in FIG. 10 is performed.

With the pattern shape measurement method and pattern shape measurement apparatus in Modified Example 1, the marker line DL is defined based on three contour points T. Thus, for example, even when noise causes position information on one contour point T to show an anomalous value, it is possible to reduce an influence of the contour point T. Thus, a shape of the opening pattern P can be measured with high accuracy.

### Modified Example 2

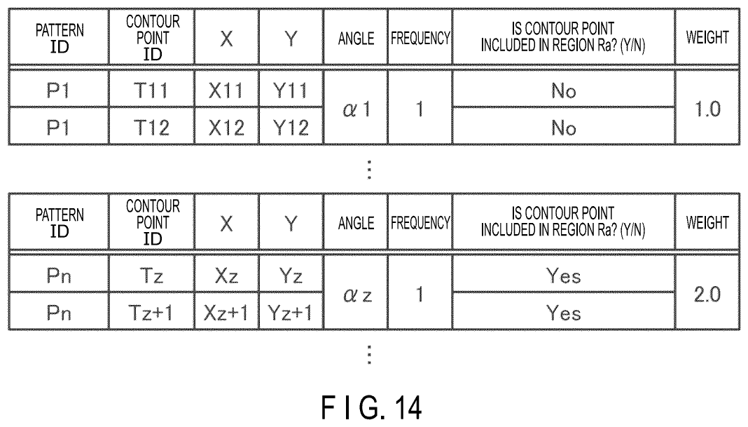

With reference to FIG. 13, Modified Example 2 of the embodiment will be described in detail. A pattern shape measurement method and a pattern shape measurement apparatus in Modified Example 2 differ from those in the embodiment described above in that extracted point data 200 is generated based on contour points T included in a predetermined region in contour point data 100. Note that, in the following, the same components as in Embodiment 1 described above will be denoted by the same reference characters, and descriptions thereof may be omitted.

FIG. 13 is a diagram illustrating a method for generating extracted point data 200 according to Modified Example 2. Note that, in the pattern shape measurement method in Modified Example 2 as well, the processing of steps S131 to 132 in FIG. 10 is assumed to be executed beforehand.

FIG. 13 illustrates a diagram in which drawing data PN on the mask substrate S illustrated in FIG. 5(A) is superimposed on the image data IM on the mask substrate S. As illustrated in FIG. 13, in the drawing data PN, regions of interest (ROI) in each of which a finish of an opening pattern P can be evaluated are specified. The regions of interest ROI are regions each satisfying a prescribed condition in the drawing data PN. The image data IM is an example of shape data.

The extracted point data generator 23 extracts, from the contour point data 100, two consecutive contour points T from contour points T included in regions Ra that overlap the regions of interest ROI in the drawing data PN and generates an item of extracted point data 200. As described above, the regions Ra are regions in the image data IM that correspond to the regions of interest ROI in the drawing data PN. That is, from any one of the contour points T included in the regions Ra, dimensions, a shape, and the like of an opening pattern P as a finished opening pattern can be specified. The regions Ra are an example of a predetermined region.

The angle calculator 24 calculates an angle α for each of the plurality of generated items of extracted point data 200.

Subsequently, processing of step S135 and the subsequent steps in FIG. 10 is performed.

With the pattern shape measurement method and pattern shape measurement apparatus in Modified Example 2, the angle α is calculated from the contour points T included in the regions Ra from which the shape, the dimensions, and the like of the opening pattern P can be specified, and based on the angle α, the scan angle of the electron beam EB is determined. Thus, it is possible to reduce a probability that the scan direction of the electron beam EB is substantially parallel to an orientation of a pattern edge of the opening pattern P in the regions Ra. Therefore, the shape of the opening pattern P can be measured with higher accuracy. In addition, angles α are calculated from a prescribed number of contour points T, and thus a time for calculating the angles α can be reduced. Thus, it is possible to enhance a calculating speed of the scan angle.

### Modified Example 3

With reference to FIG. 14, Modified Example 3 of the embodiment will be described in detail. A pattern shape measurement method and a pattern shape measurement apparatus in Modified Example 3 differ from those in the embodiment described above in that a weight (sometimes a heavy weight such as twice, three times, or more) is assigned to a frequency of an angle α calculated based on contour points T included in the regions Ra. Note that, in the following, the same components as in the embodiment described above will be denoted by the same reference characters, and descriptions thereof may be omitted.

FIG. 14 is a table showing an example of a relationship between items of extracted point data 200 and weights according to Modified Example 3.

Note that, in the pattern shape measurement method in Modified Example 3, the processing of steps S131 to 134 in FIG. 10 is assumed to be executed beforehand.

The scan angle determiner 25 determines whether at least one of contour points T in each item of extracted point data 200 that gives the corresponding angle α is included in the regions Ra described above. When at least one of the contour points T is included in the regions Ra, the scan angle determiner 25 assigns a heavy weight to a frequency of an angle α corresponding to the at least one of the contour points T compared with when none of the contour points T is included in the regions Ra. The weight is an example of a weight value.

The table illustrated in FIG. 14 shows a plurality of items of extracted point data 200 described with reference to FIG. 6(B) each of which is associated with an “angle α” calculated by the angle calculator 24, a “frequency (“1” as the number of occurrences in the present embodiment)” of the angle α, “is contour point T included in region Ra? (Yes/No),” and a “weight” for “is contour point T included in region Ra? (Yes/No).”

Specifically, in the example illustrated in FIG. 14, for example, when determining that “none of the contour points T11 and T12 is included in the regions Ra (No),” the scan angle determiner 25 sets the “weight” to “1.0.” On the other hand, for example, in a case where determining that “contour points Tz and Tz+1 are both included in the regions Ra (Yes),” the scan angle determiner 25 sets the “weight” of the case to “2.0,” which is heavy compared with in a case where both the contour points Tz and Tz+1 are determined to be not included in the regions Ra (No).

The scan angle determiner 25 determines an angle α based on each of the items of extracted point data 200 that gives a lowest value of multiplication of the “weight” set as described above and the “frequency” of the angle α as the scan angle of the electron beam EB.

Subsequently, processing of step S136 and the subsequent steps in FIG. 10 is performed.

With the pattern shape measurement method and pattern shape measurement apparatus in Modified Example 3, a heavy weight is assigned to a frequency of an angle α that is specified from contour points T any one of which is included in the regions Ra from which the shape, the dimensions, and the like of the opening pattern P can be specified. Thus, it is possible to reduce a probability that the scan direction of the electron beam EB is substantially parallel to an orientation of a pattern edge in the regions Ra. Therefore, the shape of the opening pattern P can be measured with higher accuracy.

### Modified Example 4

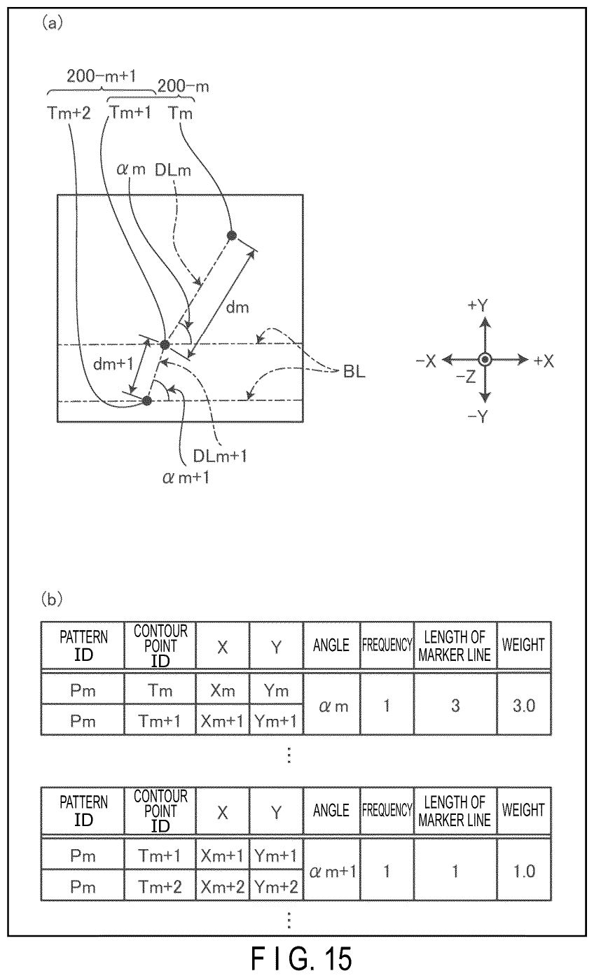

With reference to FIG. 15, Modified Example 4 of the embodiment will be described in detail. A pattern shape measurement method and a pattern shape measurement apparatus in Modified Example 4 differ from those in the embodiment described above in that a weight proportional to a length of a marker line DL is assigned. Note that, in the following, the same components as in the embodiment described above will be denoted by the same reference characters, and descriptions thereof may be omitted.

FIG. 15(A) and FIG. 15(B) are a diagram illustrating and a table showing a method for determining a scan angle according to Modified Example 4.

Note that, in the pattern shape measurement method in Modified Example 4, the processing of steps S131 to 133 in FIG. 10 is assumed to be executed beforehand.

The angle calculator 24 calculates an angle α based on each of the plurality of items of extracted point data 200 and specifies a length of a marker line DL given by the item of extracted point data 200. The scan angle determiner 25 assigns a weight proportional to the length of the marker line DL to a frequency of the angle α.

FIG. 15(A) illustrates an image including items of extracted point data 200-m and 200-m+1 out of the plurality of items of extracted point data 200. The extracted point data 200-m includes contour points Tm and Tm+1, and the extracted point data 200-m+1 includes contour points Tm+1 and Tm+2.

In an example illustrated in FIG. 15(A), the angle calculator 24 specifies an angle αm based on the extracted point data 200-m and a length dm of a marker line DLm. The angle calculator 24 also specifies an angle αm+1 based on the extracted point data 200-m+1 and a length dm+1 of the marker line DLm+1.

FIG. 15(B) is a table showing an example of a relationship between the items of extracted point data 200-m and 200-m+1 and weights. The table shown in FIG. 15(B) shows the items of extracted point data 200-m and 200-m+1 in FIG. 15(A) each of which is associated with an “angle α” calculated by the angle calculator 24, a “frequency (“1” as the number of occurrences in the present embodiment)” of the angle α, a “length of marker line” calculated by the angle calculator 24, and a “weight” for the length of the marker line.

In the example illustrated in FIG. 15(B), for example, in a case where the length dm of the marker line DLm based on the extracted point data 200-m is “3,” the scan angle determiner 25 sets the “weight” of this case to “3.0,” which is proportional to the length dm. In contrast, for example, in a case where the length dm+1 of the marker line DLm+1 based on the extracted point data 200-m+1 is “1,” the scan angle determiner 25 sets the “weight” of this case to “1.0,” which is proportional to the length dm+1.

The scan angle determiner 25 determines an angle α based on each of the items of extracted point data 200 that gives a lowest value of multiplication of the “weight” set as described above and the frequency of the angle α as the scan angle of the electron beam EB.

Subsequently, processing of step S136 and the subsequent steps in FIG. 10 is performed.

With the pattern shape measurement method and pattern shape measurement apparatus in Modified Example 4, the longer a distance between contour points T, the heavier a weight is assigned to a frequency of an angle α that is specified from the contour points T. As described above, since an interval between the contour points T is reflected in the frequency, it is possible to reduce the probability that the scan direction of the electron beam EB is substantially parallel to an orientation of a pattern edge. Thus, a shape of the opening pattern P can be measured with higher accuracy.

### Modified Example 5

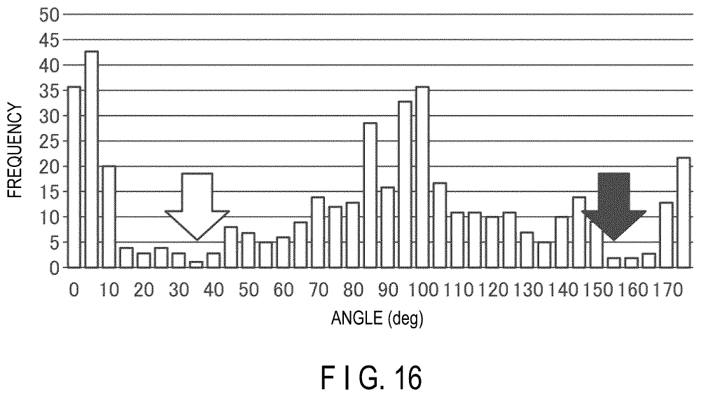

With reference to FIG. 16, Modified Example 5 of the embodiment will be described in detail. A pattern shape measurement method and a pattern shape measurement apparatus in Modified Example 5 differ from those in the embodiment described above in that a plurality of angles α are determined as scan angles in ascending order of frequency of occurrence. Note that, in the following, the same components as in the embodiment described above will be denoted by the same reference characters, and descriptions thereof may be omitted.

FIG. 16 is a graph for describing a method for determining scan angles according to Modified Example 5.

Note that, in the pattern shape measurement method in Modified Example 5, the processing of steps S131 to 134 in FIG. 10 is assumed to be executed beforehand.

The scan angle determiner 25 determines, out of the plurality of angles α, two angles α as the scan angles of the electron beam EB in ascending order of their frequencies of occurrence.

In an example of a histogram H illustrated in FIG. 16, the scan angle determiner 25 determines “35°” as a specific angle included in “35° or greater and less than 40°” and “155°” as a specific angle included in “155° or greater and less than 160°,” as the scan angles of the electron beam EB.

In addition, at this time, the scan angle determiner 25 may specify the numbers of times of scanning for “35°” and “155°” based on frequencies of the scan angles.

Specifically, the scan angle determiner 25 assigns weights such that the numbers of times of scanning for the two angles “35°” and “155°” are made larger with decreases in the frequencies of the scan angles.

In the example illustrated in FIG. 16, the frequency of “350” is assumed to be “two.” The scan angle determiner 25 sets a weight for “35°” to, for example, “½,” which is a reciprocal of the frequency. In contrast, for example, the frequency of “155°” is assumed to be “three.” The scan angle determiner 25 sets a weight for “155°” to, for example, “⅓,” which is a reciprocal of the frequency.

The scan angle determiner 25 determines the numbers of times of scanning for these “35°” and “155°” based on the weights that are set as described above. Thus, the number of times of scanning for “35°,” which has the lower frequency (fewer), is set to be larger than the number of times of scanning for 155°.”

The scan angle determiner 25 outputs the determined scan angles and numbers of times of scanning to the measurement mechanism 11. The measurement mechanism 11 scans the mask substrate S at the scan angles “35°” and “155°” the respective prescribed numbers of times determined as described above, thus generating a captured image.

Subsequently, processing of step S137 and the subsequent steps in FIG. 10 is performed.

With the pattern shape measurement method and the pattern shape measurement apparatus in Modified Example 5, it is possible to move the electron beam EB at a plurality of scan angles to generate a captured image. At this time, a larger number of scans can be performed at a scan angle having a lower frequency. Thus, a shape of the opening pattern P can be measured with higher accuracy.

### OTHER MODIFIED EXAMPLES

In the descriptions of the embodiment and modifications described above, the image data IM is used as the shape data, and a captured image is taken as an example of the image data IM. However, this is not limiting. Data other than image data, such as the design data, the drawing data PN, or the like of the mask substrate S, may be used as the shape data.

In the embodiment and modifications described above, an item of extracted point data 200 is generated including two or more consecutive contour points T. However, this is not limiting. For example, two or more inconsecutive contour points T may be extracted to generate an item of extracted point data 200.

In the embodiment and modifications described above, pieces of coordinate information each including an X coordinate and a Y coordinate are used as pieces of position information on contour points T. However, this is not limiting. For example, polar coordinates with a central point C1 of the opening pattern P1 as their origin may be used as pieces of position information.

In the embodiment and modifications described above, the reference value is assumed to be predetermined and stored in the storage 28 together with the generation of the design data on the opening patterns P. However, this is not limiting. For example, the reference value may be determined by performing shape measurement on only one of the mask substrates S created by the production process for a photomask in the embodiment illustrated in FIG. 9.

In the embodiment and modifications described above, the opening patterns P are assumed to be closed patterns. However, this is not limiting. For example, even in a case where an opening pattern P is an opened pattern that extends outside a field of view of the measurement mechanism 11, the same effect as that of the embodiment and modifications described above can be provided by applying the present invention to only a portion of the field of view.

The embodiments of the present invention are described. These embodiments are presented by way of example only and are not intended to limit the scope of the invention. These novel embodiments can be embodied in a variety of other forms; furthermore, various omissions, substitutions, and changes can be made without departing from the gist of the present invention. These embodiments and modifications thereof shall be within the scope and the gist of the invention and within the scope of the inventions described in claims and the scope of equivalents of the claims.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern shape measurement method comprising:
generating, based on shape data on a pattern being a measurement target, contour point data including pieces of position information on contour points of the pattern, the pattern being a mask pattern;
selecting sets of pieces of position information on consecutive contour points from the contour point data and generating a plurality of items of extracted point data including the respective sets of pieces of position information on consecutive contour points;
calculating, with circuitry, for each of the plurality of items of extracted point data, a determined angle formed between a marker line based on the consecutive contour points and a base line that extends in a prescribed direction in the mask pattern;
determining a scan angle for the charged particles with respect to the mask pattern based on a frequency of occurrence of the determined angle; and
scanning the mask pattern with the charged particles at the scan angle.

2. The pattern shape measurement method of claim 1, wherein the determining the scan angle of the charged particles based on the frequency of the determined angle includes determining, as the scan angle of the charged particles, the angle that is lowest in the frequency out of a plurality of the angles.

3. The pattern shape measurement method of claim 1, wherein the selecting the sets of pieces of position information on two or more consecutive contour points from the contour point data includes selecting, out of the contour point data, sets of pieces of position information on two or more consecutive contour points from among the contour points included in a predetermined region.

4. The pattern shape measurement method of claim 2, wherein the determining the scan angle of the charged particles based on the frequency of the determined angle includes:
assigning, for each of the items of extracted point data, a weight value to the frequency of the corresponding determined angle when at least one of contour points in the item of extracted point data is included in a predetermined region, the weight value being heavy compared with when the at least one of contour points is not included in the predetermined region; and
determining, as the scan angle of the charged particles, the angle that gives a lowest value of multiplication of the weight value and the frequency.

5. The pattern shape measurement method of claim 3, wherein the predetermined region is a region including contour points that enable a dimension of the mask pattern to be specified.

6. The pattern shape measurement method of claim 2, wherein the determining the scan angle of the charged particles based on the frequency of the determined angle includes:
assigning a weight value to the frequency of the determined angle, the weight value being proportional to a length of the marker line; and
determining, as the scan angle of the charged particles, the angle that gives a lowest value of multiplication of the weight value and the frequency.

7. The pattern shape measurement method of claim 1, wherein
the determining the scan angle of the charged particles based on the frequency of occurrence of the determined angle includes:
determining, as scan angles, two or more determined angles out of a plurality of determined angles in ascending order of the frequency; and
determining a plurality of number of times of scanning with the charged particles at the scan angles such that each of the plurality of number of times of scanning is made larger with a decrease in the frequency of the corresponding angle, and wherein
the scanning the mask pattern at the scan angle includes scanning the mask pattern at scan angles for the respective numbers of times of scanning.

8. The pattern shape measurement method of claim 1, wherein the shape data is at least one of image data, drawing data, and design data on the mask pattern.

9. The pattern shape measurement method of claim 1, wherein the shape data is obtained beforehand by scanning the mask pattern with charged particles.

10. A pattern shape measurement apparatus comprising:
circuitry configured to
generate, based on shape data on a pattern being a measurement target, contour point data including pieces of position information on contour points of the pattern, the pattern being a mask pattern;
select sets of pieces of position information on consecutive contour points from the contour point data and generates a plurality of items of extracted point data including the respective sets of pieces of position information on consecutive contour points;
calculate, for each of the plurality of items of extracted point data, a determined angle formed between a marker line based on the consecutive contour points and a base line that extends in a prescribed direction in the mask pattern; and
determine a scan angle of charged particles with respect to the mask pattern based on a frequency of occurrence of the determined angle.

11. The pattern shape measurement apparatus of claim 10, wherein
the circuitry comprising a central processing unit (CPU) and a non-transitory computer readable medium that has stored therein computer readable instructions that upon execution of the computer readable instructions by the CPU configure the CPU to perform predetermined operations.

12. The pattern shape measurement apparatus of claim 10, wherein the circuitry is configured to determine, as the scan angle of the charged particles, the angle that is lowest in frequency of occurrence out of a plurality of the angles.

13. The pattern shape measurement apparatus of claim 10, wherein the circuitry is configured to select, out of the contour point data, sets of pieces of position information on two or more consecutive contour points from among the contour points included in a predetermined region.

14. The pattern shape measurement apparatus of claim 12, wherein the circuitry is further configured to
assign, for each of the items of extracted point data, a weight value to the frequency of occurrence of the corresponding determined angle when at least one of contour points in the item of extracted point data is included in a predetermined region, the weight value being heavy compared with when the at least one of contour points is not included in the predetermined region, and
determine, as the scan angle of the charged particles, the angle that gives a lowest value of multiplication of the weight value and the frequency of occurrence.

15. The pattern shape measurement apparatus of claim 13, wherein the predetermined region is a region including contour points that enable a dimension of the mask pattern to be specified.

16. The pattern shape measurement apparatus of claim 12, wherein the circuitry is further configured to
assign a weight value to the frequency of occurrence of the determined angle, the weight value being proportional to a length of the marker line, and
determine, as the scan angle of the charged particles, the angle that gives a lowest value of multiplication of the weight value and the frequency of occurrence.

17. The pattern shape measurement apparatus of claim 10, wherein the circuitry is further configured to
determine, as scan angles, two or more determined angles out of a plurality of determined angles in ascending order of the frequency of occurrence, and
determine a plurality of number of times of scanning with the charged particles at the scan angles such that each of the plurality of number of times of scanning is made larger with a decrease in the frequency of occurrence of the corresponding angle.

18. The pattern shape measurement apparatus of claim 10, wherein the shape data is at least one of image data, drawing data, and design data on the mask pattern.

19. The pattern shape measurement apparatus of claim 10, wherein the shape data is obtained beforehand via a scan of the mask pattern with charged particles.

20. A method for producing a semiconductor device, comprising:
generating a pattern on a substrate under a prescribed forming condition, the pattern being a mask pattern;
generating, based on shape data on the mask pattern, contour point data including pieces of position information on contour points of the mask pattern;
selecting sets of pieces of position information on consecutive contour points from the contour point data and generating a plurality of items of extracted point data including the respective sets of pieces of position information on consecutive contour points;
calculating, for each of the plurality of items of extracted point data, a determined angle formed between a marker line based on the consecutive contour points and a base line that extends in a prescribed direction in the mask pattern;
determining a scan angle of charged particles with respect to the mask pattern based on a frequency of occurrence of the determined angle;
scanning the mask pattern at the scan angle to obtain a captured image of the mask pattern;
obtaining measurement data on the mask pattern based on the captured image;
determining whether the measurement data is within a range indicated by a reference; and
changing, after the measurement data is determined to be not within the range indicated by the reference, the forming condition for the mask pattern to a predetermined condition based on the measurement data.
